(19) United States
(12) Patent Application Publication
(10) Pub. No.: US 2026/0237597 A1
(43) Pub. Date: Aug. 13, 2026

(54) SCANNING COMPENSATION METHOD OF ELECTRON BEAM INSPECTION DEVICE, PRODUCT AND APPARATUS

(71) Applicant: Dongfang Jingyuan Electron CO, LTD., Beijing (CN)

(72) Inventors: Junhai JIANG, Beijing (CN); Shuang GAO, Beijing (CN); Yuqian LI, Beijing (CN); Jiaxin LIU, Beijing (CN)

(21) Appl. No.: 19/457,342

(22) Filed: Jan. 23, 2026

(30) Foreign Application Priority Data
Feb. 7, 2025 (CN) 202510138268.X

(51) Int. Cl. H01J 37/28; H01J 37/26

(52) U.S. Cl. CPC H01J 37/28; H01J 37/265; H01J 2237/2487

(57) ABSTRACT

Provided are a scanning compensation method of an electron beam inspection device, a product and an apparatus. The method includes: performing continuous scanning detection by the electron beam inspection device according to a preset scanning direction of a detected surface of a wafer; in the scanning detection process, driving, by a stage bearing the wafer, the wafer to displace along a preset translation direction in a plane where the detected surface is located; detecting a jitter displacement of the stage in a displacement process by a position detection apparatus, wherein the jitter displacement is a deviation between an actual position and a theoretical position of the stage in the displacement process due to mechanical jitter; and compensating a scanning waveform of the electron beam inspection device according to the jitter displacement. The scanning error caused by mechanical jitter in the displacement process of the stage is reduced.

### CROSS-REFERENCE TO RELATED APPLICATIONS

The present application claims priority to Chinese patent application No. 202510138268.X entitled “Scanning Compensation Method of Electron Beam Inspection Device, Product and Apparatus”, filed on Feb. 7, 2025, the entire contents of which are incorporated herein by reference.

### TECHNICAL FIELD

The present disclosure relates to the field of semiconductor defect detection, and particularly to a scanning compensation method of an electron beam inspection device, a product and an apparatus.

### BACKGROUND

In the current field of semiconductor defect detection, a continuous scan (CS) is different from a step scan in that a waveform generator (WG) does not output a scanning waveform in a slow scanning direction during the CS, a slow scanning deflection of the WG is replaced by a displacement of a stage in the slow scanning direction, and in a scanning line average (Line_Average) time of the WG, the stage may displace by a distance of one pixel size (Pixel_size) in the slow scanning direction. However, during the CS, a certain amount of mechanical jitter is generated due to the displacement of the stage, and the mechanical jitter is transferred to a scanned wafer, so that an acquired image has obvious jitter.

### SUMMARY

In view of the above problems, the present disclosure proposes a scanning compensation method of an electron beam inspection device, a product and an apparatus, which overcome or at least partially solve the above problems.

An object of the present disclosure is to avoid obvious jitter in an acquired image result.

A further object of the present disclosure is to compensate a scanning waveform of an electron beam.

In particular, the present disclosure provides a scanning compensation method of an electron beam inspection device, including: performing continuous scanning detection by the electron beam inspection device according to a preset scanning direction of a detected surface of a wafer; in the scanning detection process, driving, by a stage bearing the wafer, the wafer to displace along a preset translation direction in a plane where the detected surface is located, wherein a preset deflection angle exists between the preset translation direction and the preset scanning direction; detecting a jitter displacement of the stage in a displacement process by a position detection apparatus, wherein the jitter displacement is a deviation between an actual position and a theoretical position of the stage in the displacement process due to mechanical jitter; and compensating a scanning waveform of the electron beam inspection device according to the jitter displacement.

Optionally, the position detection apparatus includes a laser scale encoder, and the laser scale encoder is configured to measure position information of the stage in the displacement process; the step of detecting a jitter displacement of the stage in the displacement process by a position detection apparatus includes: acquiring the position information of the stage in the displacement process by the laser scale encoder; and calculating the jitter displacement according to the position information of the stage; the step of compensating a scanning waveform of the electron beam inspection device according to the jitter displacement includes: substituting the jitter displacement into a preset compensation algorithm model to calculate a jitter compensation quantity; and compensating the scanning waveform according to the jitter compensation quantity to obtain a compensated scanning waveform.

Optionally, the step of calculating the jitter displacement according to the position information of the stage includes: determining actual position coordinate information and a theoretical included angle of the stage in a preset coordinate system according to the position information of the stage, the theoretical included angle being an included angle between a connecting line of a theoretical position of the stage in the preset coordinate system and an original point and an x axis; and calculating the jitter displacement according to the actual position coordinate information and the theoretical included angle.

Optionally, the jitter displacement includes a scanning direction jitter displacement corresponding to the preset scanning direction; a calculation formula for calculating the scanning direction jitter displacement according to the actual position coordinate information and the theoretical included angle is as follows: |Pos_y*cosθ|−|Pos_x*sinθ|, wherein Pos_y represents a y value of the actual position coordinate information, Pos_x represents an x value of the actual position coordinate information, and θ represents the theoretical included angle.

Optionally, the jitter displacement further includes a translation direction jitter displacement corresponding to the preset translation direction; a calculation formula for calculating the translation direction jitter displacement according to the actual position coordinate information and the theoretical included angle is as follows: (|Pos_y*sinθ|+|Pos_x*cosθ|)−(pixel_size×pixel_num), wherein Pos_y represents a y value of the actual position coordinate information, Pos_x represents an x value of the actual position coordinate information, θ represents the theoretical included angle, pixel_size represents a pixel size of a single pixel in an actual image, and pixel_num represents a number of the pixels of the actual image.

Optionally, the preset compensation algorithm model is: jitter displacement*308.8/pixel_size=jitter compensation quantity/step_pixel, wherein pixel_size represents the pixel size of the single pixel in the actual image in pm, and step_pixel represents a digital quantity generated when an electron beam deflects by one pixel.

Optionally, the position detection apparatus further includes an information distribution module and a waveform transmitter; the step of calculating the jitter displacement according to the position information of the stage includes: acquiring the position information of the stage measured by the laser scale encoder and forwarding the position information of the stage to the waveform transmitter by the information distribution module; and digitizing the position information of the stage by the waveform transmitter to obtain the jitter displacement.

Optionally, after acquiring the position information of the stage measured by the laser scale encoder by the information distribution module, the method further includes: forwarding the position information of the stage to the stage by the information distribution module; determining, by the stage, whether the actual position of the stage deviates from the theoretical position according to the position information of the stage; and if yes, executing the step of compensating a scanning waveform of the electron beam inspection device according to the jitter displacement.

Optionally, the waveform transmitter includes: a decoder module, a data processing module and a digital-to-analog conversion module; the step of digitizing the position information of the stage by the waveform transmitter to obtain the jitter displacement includes: performing position decoding on the position information of the stage by the decoder module, so as to convert the position information of the stage from an analog quantity to a digital quantity to obtain decoded digital quantity position information; and calculating the jitter displacement according to the decoded digital quantity position information by the data processing module; after substituting the jitter displacement into the preset compensation algorithm model to calculate the jitter compensation quantity, the method further includes: converting the jitter compensation quantity from a digital quantity to an analog quantity by the digital-to-analog conversion module; and performing the step of compensating the scanning waveform according to the jitter compensation quantity to obtain a compensated scanning waveform according to the jitter compensation quantity in an analog quantity state.

In another aspect, the present disclosure further provides a computer program product including a computer program which, when being executed by a processor, implements the steps of the scanning compensation method of an electron beam inspection device in any one of the above descriptions.

In yet another aspect, the present disclosure further provides a computer apparatus including a memory, a processor and a machine executable program stored in the memory and run on the processor, wherein the processor, when executing the machine executable program, implements the steps of the scanning compensation method of an electron beam inspection device in any one of the above descriptions.

In the scanning compensation method of an electron beam inspection device according to the present disclosure, the continuous scanning detection is performed by the electron beam inspection device according to the preset scanning direction of the detected surface of the wafer; in the scanning detection process, the wafer is driven by the stage bearing the wafer to displace along the preset translation direction in the plane where the detected surface is located, with the p reset deflection angle existing between the preset translation direction and the preset scanning direction; the jitter displacement of the stage in the displacement process is detected by the position detection apparatus, and the jitter displacement is the deviation between the actual position and the theoretical position of the stage in the displacement process due to the mechanical jitter; and the scanning waveform of the electron beam inspection device is compensated according to the jitter displacement. With the method, the scanning waveform of the electron beam inspection device can be compensated through the detected jitter displacement, so that the electron beam performs scanning following the compensated scanning waveform, thereby effectively reducing a scanning error caused by the mechanical jitter in the displacement process of the stage, eliminating the image jitter in the scanning result, and making the scanning result closer to a real condition of the surface of the wafer.

According to the following detailed description of specific embodiments of the present disclosure in conjunction with drawings, those skilled in the art will better understand the aforementioned and other objects, advantages and features of the present disclosure.

### BRIEF DESCRIPTION OF THE DRAWINGS

Some specific embodiments of the present disclosure will be described below in detail in an exemplary rather than restrictive manner with reference to the drawings. Identical reference numerals in the drawings represent identical or similar components or parts. Those skilled in the art should understand that these drawings are not necessarily drawn to scale. In the drawings:

FIG. 1 is a schematic flow diagram of a scanning compensation method of an electron beam inspection device according to an embodiment of the present disclosure;

FIG. 2 is a schematic flow diagram of a scanning compensation method of an electron beam inspection device according to another embodiment of the present disclosure;

FIG. 3 is a schematic diagram of a preset coordinate system in a scanning detection process in an embodiment of the present disclosure;

FIG. 4 is a schematic diagram of a calculation principle of the scanning detection process in an embodiment of the present disclosure;

FIG. 5A is a schematic diagram of a scanned image result before compensation is performed in an embodiment of the present disclosure;

FIG. 5B is a schematic diagram of a scanned image result after the compensation is performed in an embodiment of the present disclosure;

FIG. 6 is a schematic structural diagram of a computer program product according to an embodiment of the present disclosure;

FIG. 7 is a schematic structural diagram of a computer-readable storage medium according to an embodiment of the present disclosure; and

FIG. 8 is a schematic structural diagram of a computer apparatus according to an embodiment of the present disclosure.

### DETAILED DESCRIPTION OF THE EMBODIMENTS

It should be understood by those skilled in the art that the embodiments described below are only some embodiments of the present disclosure and not all embodiments of the present disclosure, and the embodiments are intended to explain the technical principle of the present disclosure and not to limit the scope of the present disclosure. All other embodiments obtained by a person of ordinary skill in the art based on the embodiments of the present disclosure without creative efforts shall fall within the protection scope of the present disclosure.

It should be noted that the logic and/or steps described in the flow charts or in other manners, e.g., a sequential list of executable instructions for implementing logic functions, may be implemented in any computer-readable medium for usage of instruction execution systems, apparatuses or devices, such as computer-based systems, systems including processors, or other systems which can read instructions from the instruction execution systems, apparatuses or devices and execute them, or in combination with the instruction execution systems, apparatuses or devices to use.

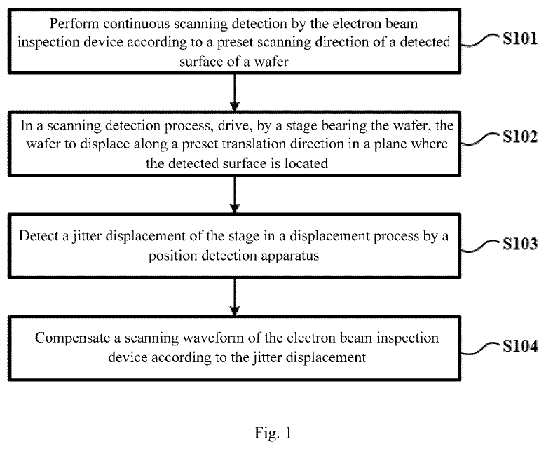

FIG. 1 is a schematic flow diagram of a scanning compensation method of an electron beam inspection device according to an embodiment of the present disclosure. As shown in FIG. 1, the scanning compensation method of an electron beam inspection device at least includes the following step S101 to step S104.
Step S101: performing continuous scanning detection by the electron beam inspection device according to a preset scanning direction of a detected surface of a wafer.
Step S102: in a scanning detection process, driving, by a stage bearing the wafer, the wafer to displace along a preset translation direction in a plane where the detected surface is located. A preset deflection angle exists between the preset translation direction and the preset scanning direction.
Step S103: detecting a jitter displacement of the stage in a displacement process by a position detection apparatus. The jitter displacement is a deviation between an actual position and a theoretical position of the stage in the displacement process due to mechanical jitter. The stage inevitably generates jitter during movement due to factors, such as mechanical vibration and unstable operation of a motor. The jitter causes a deviation of an electron beam from an ideal path during scanning, which affects accuracy of a detection result, and therefore the jitter displacement of the stage at each position during scanning needs to be detected, so as to compensate an error later.

In some optional embodiments, the position detection apparatus may generally include a laser scale encoder, and the laser scale encoder is configured to measure position information of the stage in the displacement process. The step of detecting a jitter displacement of the stage in the displacement process by a position detection apparatus may generally include: acquiring the position information of the stage in the displacement process by the laser scale encoder; and calculating the jitter displacement according to the position information of the stage.
Step S104: compensating a scanning waveform of the electron beam inspection device according to the jitter displacement. The scanning waveform of the electron beam inspection device is adjusted according to the jitter displacement of the stage detected in the step S103, so that the scanning waveform of the electron beam is consistent with a moving position of the stage after the jitter, and thus, the deviation caused by the jitter can be corrected in an actual scanning path of the electron beam.

With the method, the scanning waveform of the electron beam inspection device can be compensated through the detected jitter displacement, so that the electron beam performs scanning following the compensated scanning waveform, thereby effectively reducing a scanning error caused by the mechanical jitter in the displacement process of the stage, eliminating the image jitter in the scanning result, making the scanning result closer to a real condition of the surface of the wafer, and facilitating accurate judgment of quality and defects of the wafer.

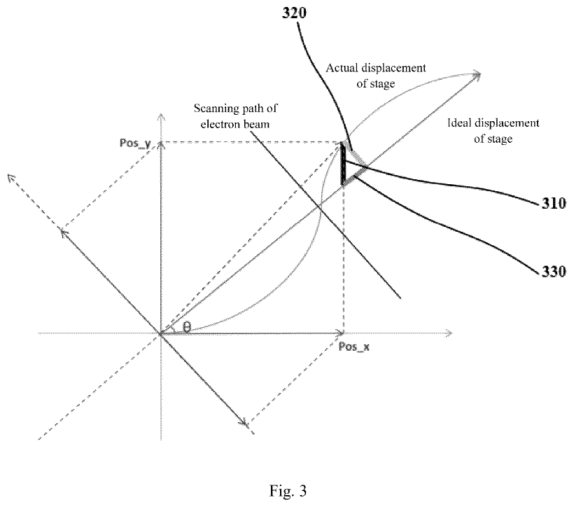

In some optional embodiments, the step of calculating the jitter displacement according to the position information of the stage may generally include: determining actual position coordinate information and a theoretical included angle of the stage in a preset coordinate system according to the position information of the stage, the theoretical included angle being an included angle between a connecting line of a theoretical position of the stage in the preset coordinate system and an original point and an x axis; and calculating the jitter displacement according to the actual position coordinate information and the theoretical included angle. An optional example of the preset coordinate system is shown in FIG. 3, FIG. 3 is a schematic diagram of the preset coordinate system in the scanning detection process in an embodiment of the present disclosure, and it can be seen from FIG. 3 that an ideal displacement path of the stage is a straight line and has an included angle θ relative to the x axis of the coordinate system, that is, the theoretical included angle is θ. In addition, there is an electron beam scanning path perpendicular to the ideal displacement path of the stage. In the drawing, the line segment 310 is the jitter displacement of the stage, i.e., the deviation between the actual position and the theoretical position of the stage in the displacement process due to the mechanical jitter. It should be noted that the path and the preset coordinate system shown in FIG. 3 are only an optional example, the electron beam scanning path may be perpendicular to the ideal displacement path of the stage, or may be at a set deflection angle relative to the ideal displacement path, and those skilled in the art may set the ideal displacement path of the stage, the electron beam scanning path and the preset coordinate system according to an actual situation.

Optionally, the jitter displacement may generally include a scanning direction jitter displacement corresponding to the preset scanning direction. Also referring to FIG. 3 as an example, the line segment 320 in FIG. 3 is the scanning direction jitter displacement corresponding to the preset scanning direction. As can be seen from FIG. 3, a jitter digital quantity is obtained by subtracting an ideal position digital quantity from an actual position digital quantity, and therefore, a calculation formula for calculating the scanning direction jitter displacement according to the actual position coordinate information and the theoretical included angle may be the following formula 1:

$$\vert Pos\_y * cos θ \vert - \vert Pos\_x * sin θ \vert \qquad formula 1$$

wherein Pos_y represents a y value of the actual position coordinate information, Pos_x represents an x value of the actual position coordinate information, and θ represents the theoretical included angle. The jitter digital quantity corresponding to the scanning direction jitter displacement can be calculated by the formula 1.

A specific calculation principle is shown in FIG. 4, FIG. 4 is a schematic diagram of the calculation principle of the scanning detection process in an embodiment of the present disclosure, and a plurality of auxiliary lines are added in FIG. 4 to assist the description, in which the line segment AB represents the scanning direction jitter displacement, the line segment AB is lengthened to the x axis to obtain the point E, a perpendicular line is drawn from the point F to the line segment OB to obtain the line segment GF, a perpendicular line is drawn from the point F to the line segment AE to obtain the line segment DF, and the angle BAC is equal to the angle θ. A length of the line segment AD can be obtained by Pos_y*cosθ, a length of the line segment GF can be obtained by Pos_x*sinθ, and since GF=BD, |Pos_y*cosθ|−|Pos_x*sinθ|=AB, i.e., the scanning direction jitter displacement corresponding to the preset scanning direction.

In addition to the scanning direction jitter displacement, the jitter displacement includes a translation direction jitter displacement corresponding to the preset translation direction. Still referring to FIG. 3 as an example, the line segment 330 is the translation direction jitter displacement corresponding to the preset translation direction. A calculation formula for calculating the translation direction jitter displacement according to the actual position coordinate information and the theoretical included angle may be the following formula 2:

$$( \vert Pos\_y * sin θ \vert + \vert Pos\_x * cos θ \vert ) - ( pixel\_size \times pixel\_num ) \qquad formula 2$$

wherein Pos_y represents the y value of the actual position coordinate information, Pos_x represents the x value of the actual position coordinate information, θ represents the theoretical included angle, pixel_size represents a pixel size of a single pixel in an actual image, and pixel_num represents a number of the pixels of the actual image. The translation direction jitter displacement corresponding to the preset translation direction can be calculated by the formula 2.

Still referring to FIG. 4, a length of the line segment DF can be obtained by Pos_y*sinθ, and since DF=BG, a length of the line segment BG can be obtained by Pos_y*sinθ; a length of the line segment OG can be obtained by Pos_x*cosθ, and a sum of the lengths of BG and OG can be obtained by (|Pos_y*sinθ|+|Pos_x*cosθ|), i.e., a length of the line segment OB; an ideal displacement of the stage, i.e., a length of the line segment OC, can be calculated by pixel_size×pixel_num, and OB−OC=CB, thus the translation direction jitter displacement corresponding to the preset translation direction can be obtained.

After the jitter displacement is calculated, the step S104 of compensating a scanning waveform of the electron beam inspection device according to the jitter displacement needs to be performed. In some optional embodiments, the step of compensating a scanning waveform of the electron beam inspection device according to the jitter displacement may generally include: substituting the jitter displacement into a preset compensation algorithm model to calculate a jitter compensation quantity; and compensating the scanning waveform according to the jitter compensation quantity to obtain a compensated scanning waveform.

Optionally, the preset compensation algorithm model is:
jitter displacement*308.8/pixel_size=jitter compensation quantity/step_pixel
wherein pixel_size represents the pixel size of the single pixel in the actual image in pm, and step_pixel represents a digital quantity generated when an electron beam deflects by one pixel. The preset compensation algorithm model establishes a relationship between the jitter displacement and the jitter compensation quantity through a proportional relationship. The “jitter displacement*308.8/pixel_size” on the left side of the formula is intended to convert the jitter displacement according to a certain proportional relationship, wherein 308.8 is a decoder card resolution. The “jitter compensation quantity/step_pixel” on the right side represents a proportional relationship between the jitter compensation quantity and the digital quantity generated when the electron beam deflects by one pixel. Through the formula, the jitter compensation quantity required to adjust the scanning waveform can be calculated according to the actually detected jitter displacement, so that the scanning waveform is accurately compensated.

In some optional embodiments, the position detection apparatus may further include an information distribution module and a waveform transmitter. The information distribution module may be an EM64 module, and the EM64 module generally refers to an information distribution component supporting an extended memory 64 technology. In the position detection apparatus, the EM64 module is mainly responsible for efficiently distributing and transmitting various data information acquired by the position detection apparatus. The waveform transmitter can perform processing and calculation according to preset parameters to finally generate the required scanning waveform, so that the electron beam is controlled to perform scanning according to the corresponding scanning waveform. Therefore, the step of calculating the jitter displacement according to the position information of the stage may generally include: acquiring the position information of the stage measured by the laser scale encoder and forwarding the position information of the stage to the waveform transmitter by the information distribution module; and digitizing the position information of the stage by the waveform transmitter to obtain the jitter displacement.

In some other optional embodiments, after acquiring the position information of the stage measured by the laser scale encoder by the information distribution module, the method may generally further include: forwarding the position information of the stage to the stage by the information distribution module; determining, by the stage, whether the actual position of the stage deviates from the theoretical position according to the position information of the stage; and if yes, executing the step of compensating a scanning waveform of the electron beam inspection device according to the jitter displacement. With this operation, whether the deviation occurs or not can be determined by the stage, and then, whether the compensation is performed or not can be determined, so that starting and stopping of the compensation method can be determined according to an actual condition of the stage, thereby avoiding unnecessary consumption of computer resources.

Optionally, the waveform transmitter may generally include: a decoder module, a data processing module and a digital-to-analog conversion module. Data generally can be divided into analog quantities and digital quantities, and a digital quantity has discrete and discontinuous values, and usually has only a limited number of or several values. Generally, the digital quantity is typically represented by a binary code having only two states: 0 and 1, such as high and low levels in digital circuits or binary data bits in computers. An analog quantity is a physical quantity with continuously changed times and numerical values, a value of the analog quantity can be any real number, and the analog quantity has an infinite number of possible values. For example, physical quantities such as temperature, pressure, voltage, and current are usually analog quantities in practice, and may vary continuously within a certain range without definite discrete intervals. However, when the data processing module performs data processing, digital quantities are generally required to be used for calculation, and the position information of the stage received by the waveform transmitter is generally an analog quantity, and therefore, the waveform transmitter needs to convert the jitter displacement to facilitate subsequent calculation.

The step of digitizing the position information of the stage by the waveform transmitter to obtain the jitter displacement may generally include: performing position decoding on the position information of the stage by the decoder module, so as to convert the position information of the stage from an analog quantity to a digital quantity to obtain decoded digital quantity position information; and calculating the jitter displacement according to the decoded digital quantity position information by the data processing module. An optional example of the decoder module is a Decoder which is generally configured to convert an encoded signal collected by a sensor into an actual digital quantity.

After the calculation of the waveform transmitter is finished, the digital quantity is still required to be converted into the analog quantity, and therefore, after substituting the jitter displacement into the preset compensation algorithm model to calculate the jitter compensation quantity, the method may generally further include: converting the jitter compensation quantity from a digital quantity to an analog quantity by the digital-to-analog conversion module; and performing the step of compensating the scanning waveform according to the jitter compensation quantity to obtain a compensated scanning waveform according to the jitter compensation quantity in an analog quantity state. An optional example of the digital-to-analog conversion module is a digital-to-analog converter (DAC) chip, and those skilled in the art can determine a specific processing apparatus inside the waveform transmitter according to actual situations.

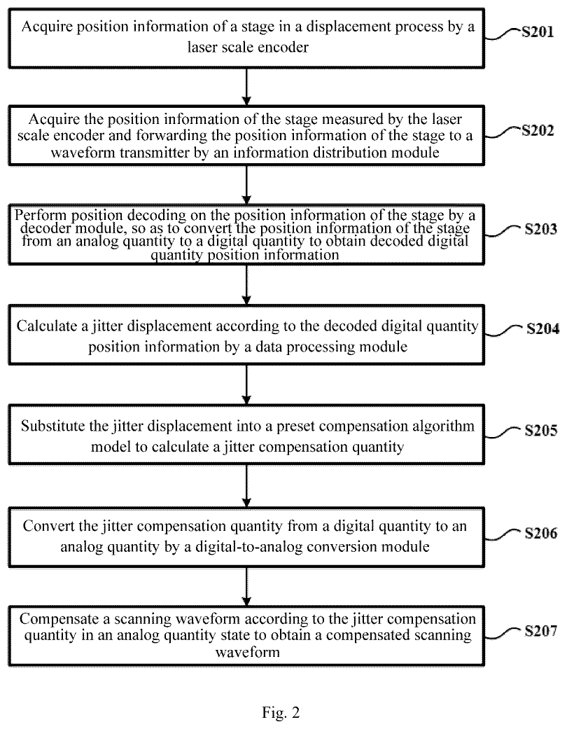

FIG. 2 is a schematic flow diagram of a scanning compensation method of an electron beam inspection device according to another embodiment of the present disclosure. As shown in FIG. 2, the scanning compensation method of an electron beam inspection device at least includes the following step S201 to step S207.
Step S201: acquiring position information of a stage in a displacement process by a laser scale encoder. The laser scale encoder monitors a position of the stage in the displacement process in real time by using a laser measurement principle thereof, so as to obtain the position information of the stage. The laser scale encoder emits a laser beam, receives reflected light, and determines a change of a distance between the stage and the laser scale encoder according to a laser propagation time, a phase difference, or the like, so as to obtain the position information of the stage. In this way, raw data on an actual position of the stage can be provided for subsequent analysis and processing.
Step S202: acquiring the position information of the stage measured by the laser scale encoder and forwarding the position information of the stage to a waveform transmitter by an information distribution module. The information distribution module (e.g., EM64 module) acquires the measured position information of the stage (an analog quantity signal) from the laser scale encoder and forwards this information to the waveform transmitter and a subsequent decoder module.
Step S203: performing position decoding on the position information of the stage by the decoder module, so as to convert the position information of the stage from an analog quantity to a digital quantity to obtain decoded digital quantity position information. Since the digital quantity is more suitable for processing and analysis by computers and digital circuits, the decoder module (e.g., a Decoder) receives the position information of the stage in the analog quantity form from the EM64 module and then performs position decoding on the information. The decoding process includes converting the continuously changed analog quantity into the discrete digital quantity according to specific encoding rules and algorithms, and finally obtaining the decoded digital quantity position information. After the analog quantity is converted into the digital quantity, the position information of the stage can be calculated and processed more accurately by utilizing a digital signal processing technology.
Step S204: calculating a jitter displacement according to the decoded digital quantity position information by a data processing module. The data processing module receives the decoded digital quantity position information and calculates the jitter displacement of the stage in the displacement process according to a preset algorithm. The jitter displacement reflects a deviation between the actual position and an ideal position of the stage due to jitter of the stage, thereby quantifying a degree of influence of the jitter of the stage on the position of the stage.

The preset algorithm may be generally: jitter digital quantity=actual position digital quantity-ideal position digital quantity In combination with the preset coordinate system shown in FIG. 3, the line segment 320 is a scanning direction jitter displacement corresponding to a preset scanning direction, and the line segment 330 is a translation direction jitter displacement corresponding to a preset translation direction. The jitter digital quantity corresponding to the scanning direction jitter displacement can be calculated through the formula 1, and the jitter digital quantity corresponding to the translation direction jitter displacement can be calculated through the formula 2.
Step S205: substituting the jitter displacement into a preset compensation algorithm model to calculate a jitter compensation quantity.
Step S206: converting the jitter compensation quantity from a digital quantity to an analog quantity by a digital-to-analog conversion module.
Step S207: compensating a scanning waveform according to the jitter compensation quantity in an analog quantity state to obtain a compensated scanning waveform. The compensation quantity is applied to relevant parameters (such as an amplitude and a phase) of the scanning waveform through a specific circuit or algorithm, so as to obtain the compensated scanning waveform. Therefore, the influence of the jitter of the stage on the scanning waveform of the electron beam can be eliminated or reduced, the scanning waveform can more accurately reflect an actual condition of a measured object, and precision and reliability of electron beam inspection are improved.

To sum up, a specific processing method according to this embodiment is as follows: the laser scale encoder sends the position information of the stage to the EM64 module, the EM64 module forwards the analog quantity signal to the Decoder module for position decoding, the WG calculates the digital quantity of the scanning waveform corresponding to the jitter displacement of the stage according to the decoded digital quantity position information, and then, dynamic compensation is completed.

With the method, the scanning waveform of the electron beam inspection device can be compensated through the detected jitter displacement, so that the electron beam performs scanning following the compensated scanning waveform, thereby effectively reducing a scanning error caused by the mechanical jitter in the displacement process of the stage, eliminating image jitter in a scanning result, making the scanning result closer to a real condition of a surface of a wafer, and facilitating accurate judgment of quality and defects of the wafer.

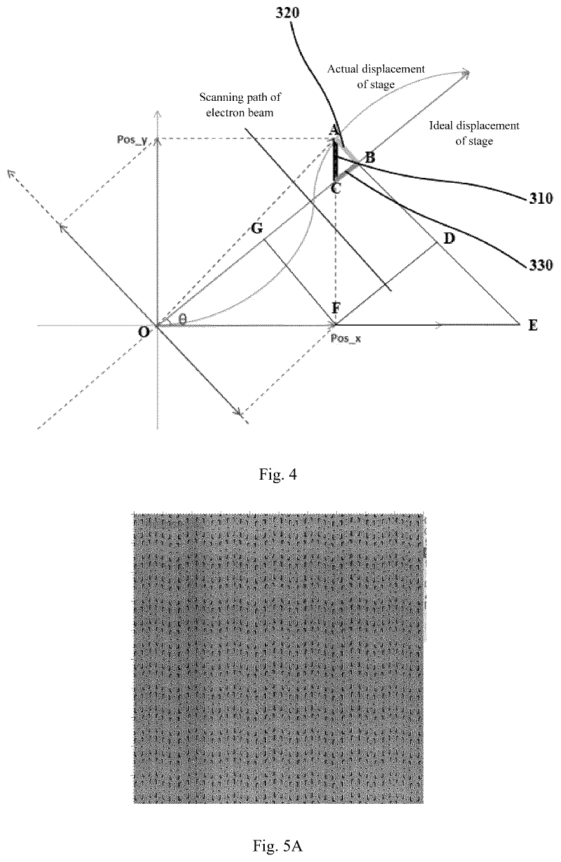

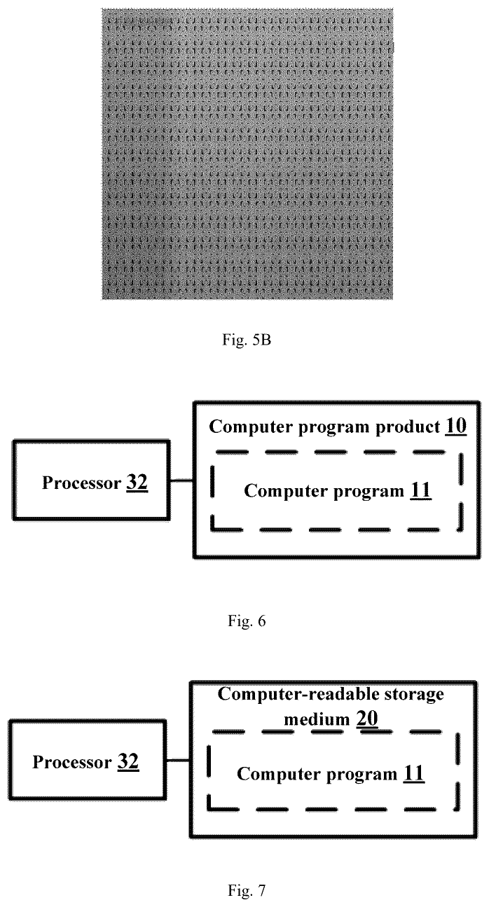

In order to clearly show an effect of the method according to the present disclosure, a pair of comparison graphs of the effect before and after the compensation method according to the present disclosure is used is provided. FIG. 5A is a schematic diagram of a scanned image result before compensation is performed in an embodiment of the present disclosure, and FIG. 5B is a schematic diagram of a scanned image result after the compensation is performed in an embodiment of the present disclosure. As can be seen from FIG. 5A, during a CS, a certain amount of mechanical jitter is generated due to a displacement of a stage, and the mechanical jitter is transferred to a scanned wafer, so that a scanned image also has jitter, which seriously affects subsequent detection of the wafer. However, after dynamic compensation is performed by using the method according to the present disclosure, a scanned image is shown in FIG. 5B, and in the case that the stage has a jitter displacement, a scanning waveform of an electron beam also jitters by a same amplitude, so that the image jitter in the scanning result can be eliminated in the scanned image, and the scanning result is closer to a real condition of a surface of the wafer.

The flow charts provided in the embodiments are not intended to indicate that the operations of the method are to be performed in any particular order, or that all of the operations of the method are to be included in each case. Further, the method may include additional operations. Additional variations on the above-described method are possible within the scope of the technical idea provided by the method according to the embodiments.

It should be understood that, in some embodiments, each element may be implemented with hardware, software, firmware or a combination thereof. In the above implementation, a plurality of steps or methods may be implemented in software or firmware which is stored in a memory and executed by a suitable instruction execution system.

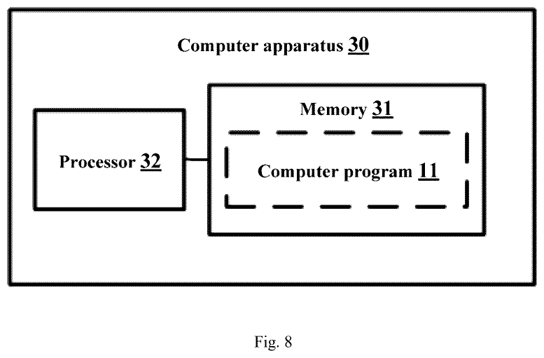

The embodiments further provide a computer program product 10, a computer-readable storage medium 20 and a computer apparatus 30. FIG. 6 is a schematic structural diagram of the computer program product 10 according to an embodiment of the present disclosure, FIG. 7 is a schematic structural diagram of the computer-readable storage medium 20 according to an embodiment of the present disclosure, and FIG. 8 is a schematic structural diagram of the computer apparatus 10 according to an embodiment of the present disclosure. The computer program product 10 includes a computer program 11 which, when being executed by a processor 32, implements the steps of the scanning compensation method of an electron beam inspection device in any one of the above descriptions. The computer-readable storage medium 20 has stored the above computer program 11 therein, and when the computer program 11 is executed by the processor 32, the steps of the scanning compensation method of an electron beam inspection device according to any of the embodiments described above are implemented. The computer apparatus 30 may include a memory 31, a processor 32 and a computer program 11 which is stored in the memory 31 and run on the processor 32.

The computer program 11 for performing operations of the present disclosure may be assembler instructions, instruction set architecture (ISA) instructions, machine instructions, machine-related instructions, microcodes, firmware instructions, state setting data, configuration data for an integrated circuit, or source or object codes written in any combination of one or more programming languages and procedural programming languages. The computer program 11 may be executed entirely on a computer of a user, partly on the computer of the user, as a stand-alone software package, partly on the computer of the user and partly on a remote computer, or entirely on the remote computer or a server. In the latter scenario, the remote computer may be connected to the computer of the user through any type of network, including a local area network (LAN) or a wide area network (WAN), or connected to an external computer (for example, through the Internet using an Internet service provider). In some embodiments, in order to perform the aspects of the present disclosure, an electronic circuit including, for example, a programmable logic circuit, a field-programmable gate array (FPGA) or a programmable logic array (PLA), may be personalized by executing computer-readable program instructions with state information of the computer-readable program instructions.

In the description of this embodiment, the computer program product 10 is a related product including the computer program 11. In the description of this embodiment, the computer-readable storage medium 20 is a tangible device capable of reserving and storing the computer program 11, and may be any apparatus that contains, stores, communicates, propagates or transmits the program 11 for an instruction execution system, apparatus or device or in combination therewith for the usage. More specific examples (a non-exhaustive list) of the computer-readable storage medium 20 include a portable computer disk, a hard disk, a random access memory (RAM), a read-only memory (ROM), an erasable programmable read-only memory (EPROM or flash memory), a static random access memory (SRAM), a portable compact disc read-only memory (CD-ROM), a digital versatile disc (DVD), a memory stick, a floppy disk, a mechanical encoding device, and any suitable combination of the foregoing.

The computer apparatus 30 may be, for example, a server, a desktop computer, a notebook computer, a tablet computer, or a smartphone. In some examples, the computer apparatus 30 may be a cloud computing node. The computer apparatus 30 may be described in the general context of computer system-executable instructions (such as program modules) executed by a computer system. Generally, the program modules may include routines, programs, object programs, components, logic, data structures, or the like, that perform particular tasks or implement particular abstract data types. The computer apparatus 30 may be implemented in a distributed cloud computing environment where tasks are performed by remote processing devices that are linked through a communication network. In the distributed cloud computing environment, the program modules may be located in storage media of a local or remote computing system including storage devices.

The computer apparatus 30 may include a processor 32 adapted to execute stored instructions, and a memory 31 that provides a temporary storage space for operations of the instructions during operations. The processor 32 may be a single-core processor, a multi-core processor, a computing cluster, or any number of other configurations. The memory 31 may include a random access memory (RAM), a read-only memory, a flash memory, or any other suitable storage systems.

The computer apparatus 30 may also include a network adapter/interface and an input/output (I/O) interface. The I/O interface allows data to be input and output with an external device that can be connected to the computer apparatus. The network adapter/interface may provide communication between the computer apparatus and a network shown generally as a communication network.

So far, those skilled in the art should be aware that, although plural exemplary embodiments of the present disclosure have been shown and described herein in detail, a lot of other variations or modifications conforming to the principle of the present disclosure can still be directly determined or derived from the contents disclosed in the present disclosure without departing from the spirit and scope of the present disclosure. Therefore, the scope of the present disclosure should be understood and deemed as covering all of these other variations or modifications.

What is claimed is:

1. A scanning compensation method of an electron beam inspection device, comprising:
performing continuous scanning detection by the electron beam inspection device according to a preset scanning direction of a detected surface of a wafer;
in a scanning detection process, driving, by a stage bearing the wafer, the wafer to displace along a preset translation direction in a plane where the detected surface is located, wherein a preset deflection angle exists between the preset translation direction and the preset scanning direction;
detecting a jitter displacement of the stage in a displacement process by a position detection apparatus, wherein the jitter displacement is a deviation between an actual position and a theoretical position of the stage in the displacement process due to mechanical jitter; and
compensating a scanning waveform of the electron beam inspection device according to the jitter displacement.

2. The scanning compensation method of an electron beam inspection device according to claim 1,
wherein the position detection apparatus comprises a laser scale encoder, and the laser scale encoder is configured to measure position information of the stage in the displacement process;
the step of detecting a jitter displacement of the stage in the displacement process by a position detection apparatus comprises: acquiring the position information of the stage in the displacement process by the laser scale encoder; and calculating the jitter displacement according to the position information of the stage;
the step of compensating a scanning waveform of the electron beam inspection device according to the jitter displacement comprises: substituting the jitter displacement into a preset compensation algorithm model to calculate a jitter compensation quantity; and compensating the scanning waveform according to the jitter compensation quantity to obtain a compensated scanning waveform.

3. The scanning compensation method of an electron beam inspection device according to claim 2,
wherein the step of calculating the jitter displacement according to the position information of the stage comprises:
determining actual position coordinate information and a theoretical included angle of the stage in a preset coordinate system according to the position information of the stage, the theoretical included angle being an included angle between a connecting line of a theoretical position of the stage in the preset coordinate system and an original point and an x axis; and
calculating the jitter displacement according to the actual position coordinate information and the theoretical included angle.

4. The scanning compensation method of an electron beam inspection device according to claim 3,
wherein the jitter displacement comprises a scanning direction jitter displacement corresponding to the preset scanning direction;
a calculation formula for calculating the scanning direction jitter displacement according to the actual position coordinate information and the theoretical included angle is as follows:

|Pos_y*cosθ|−|Pos_x*sinθ|

wherein Pos_y represents a y value of the actual position coordinate information, Pos_x represents an x value of the actual position coordinate information, and θ represents the theoretical included angle.

5. The scanning compensation method of an electron beam inspection device according to claim 3,
wherein the jitter displacement comprises a translation direction jitter displacement corresponding to the preset translation direction;
a calculation formula for calculating the translation direction jitter displacement according to the actual position coordinate information and the theoretical included angle is as follows:
(|Pos_y*sinθ|+|Pos_x*cosθ|)−(pixel_size×pixel_num)
wherein Pos_y represents a y value of the actual position coordinate information, Pos_x represents an x value of the actual position coordinate information, θ represents the theoretical included angle, pixel_size represents a pixel size of a single pixel in an actual image, and pixel_num represents a number of the pixels of the actual image.

6. The scanning compensation method of an electron beam inspection device according to claim 2,
wherein the preset compensation algorithm model is:
jitter displacement*308.8/pixel_size=jitter compensation quantity/step_pixel
wherein pixel_size represents a pixel size of a single pixel in the actual image in pm, and step_pixel represents a digital quantity generated when an electron beam deflects by one pixel.

7. The scanning compensation method of an electron beam inspection device according to claim 2,
wherein the position detection apparatus further comprises an information distribution module and a waveform transmitter;
the step of calculating the jitter displacement according to the position information of the stage comprises:
acquiring the position information of the stage measured by the laser scale encoder and forwarding the position information of the stage to the waveform transmitter by the information distribution module; and
digitizing the position information of the stage by the waveform transmitter to obtain the jitter displacement.

8. The scanning compensation method of an electron beam inspection device according to claim 7,
wherein after acquiring the position information of the stage measured by the laser scale encoder by the information distribution module, the method further comprises:
forwarding the position information of the stage to the stage by the information distribution module;
determining, by the stage, whether the actual position of the stage deviates from the theoretical position according to the position information of the stage; and
if yes, executing the step of compensating a scanning waveform of the electron beam inspection device according to the jitter displacement.

9. A computer program product comprising a computer program which, when being executed by a processor, implements the steps of the scanning compensation method of an electron beam inspection device according to claim 1.

10. A computer apparatus comprising a memory, a processor and a machine executable program stored in the memory and run on the processor, wherein the processor, when executing the machine executable program, implements the steps of the scanning compensation method of an electron beam inspection device according to claim 1.
